(19) United States
(12) Patent Application Publication
(10) Pub. No.: US 2017/0265309 A1
(43) Pub. Date: Sep. 14, 2017

(54) PRINTER AND A METHOD FOR PRINTING INK ON A SUBSTRATE

(71) Applicants: ELI ASULIN, Yokneam Ilit (IL); YARIV PINTO, Petach Tiqwa (IL)

(72) Inventors: ELI ASULIN, Yokneam Ilit (IL); YARIV PINTO, Petach Tiqwa (IL)

(21) Appl. No.: 15/456,530

(22) Filed: Mar. 12, 2017

Related U.S. Application Data
(60) Provisional application No. 62/307,512, filed on Mar. 13, 2016.

(51) Int. Cl. H05K 3/00; B41J 11/00; B41J 2/01

(52) U.S. Cl. CPC H05K 3/0091; B41J 2/01; B41J 11/0015

(57) ABSTRACT

A method for applying ink to a printed circuit board to form a pattern, the method may include flooding the printed circuit board with ink, such that the ink advances within edges of the pattern; freezing the ink before the ink exceeds the edges of the pattern; and vibrating the printed circuit board during a vibration period that at least partially overlaps at least one of the flooding and the freezing.

### CROSS REFERENCE

This application claims the priority of U.S. provisional patent Ser. No. 62/307512 filing date Mar. 13 2016, which is incorporated herein by reference.

### BACKGROUND

A common prior art method for solder mask application on high end PCBs is photolithography, which includes the following steps: (a) pre-clean and rinse of board, (b) full coating of the panel with liquid photo imageable solder mask, (c) Tack free drying of both sides of the board, (d) exposure to actinic light through a photo tool (usually under vacuum), (e) development, (f) cascade rinsing and (g) final curing of the board.

There is a need to provide a fast method for printing a solder mask.

### SUMMARY

There may be provided a method for applying ink to a substrate to form a pattern, the method may include performing a single printing iteration that may include flooding, using jets of ink, the substrate with ink, such that the ink advances within edges of the pattern; and freezing the ink before the ink exceeds the edges of the pattern by irradiating the ink with radiation.

The method may include vibrating the substrate during a vibration period that at least partially overlaps at least one of the flooding and the freezing.

There may be provided a method for applying ink to a printed circuit board to form a pattern, the method may include flooding the printed circuit board with ink, such that the ink advances within edges of the pattern; freezing the ink before the ink exceeds the edges of the pattern; and vibrating the printed circuit board during a vibration period that at least partially overlaps at least one of the flooding and the freezing.

The method may include vibrating the printed circuit board during the entire printing period.

The printing period may end when the freezing starts or before the freezing starts.

The vibrating may end after the freezing starts.

The vibrating may include introducing vibrations that may be identical to each other.

The vibrating may include introducing vibrations that differ from each other.

The vibrating may include reducing an intensity of vibrations towards an end of the printing period.

The vibrating may start after the completion of the ink jetting. The ink jetting may resume after freezing the ink. For instance, the entire laminate area of a PCB may be printed in a first jetting pass, vibrating the boards may start within a second from the jetting and may last between 1 and 60 seconds, then, more ink jetting passes may be performed to cover the copper and increase ink thickness on the laminate area.

The flooding may be executed by a printing unit; and wherein the method may include determining at least one parameter out of a vibrating parameter, a flooding parameter and a freezing parameter in response to an occurrence of a failure of the printing unit.

The at least one parameter may include a delay between a beginning of the flooding and a beginning of the freezing.

The method may include expanding the delay when the failure of the printing unit may be a non-printing nozzle of a printing unit.

The method may include detecting the occurrence of the failure of the printing unit by image processing an image of previous pattern that was previously printed by the printing unit.

The flooding may include flooding one or more regions of the substrate; and printing ink on one or more other regions of the substrate without flooding the one or more other regions.

The flooding may include flooding a region of the substrate; wherein the flooding of the region may be preceded by printing without flooding a border of the region.

The pattern may be delimited by elevated pads; and wherein the freezing may be executed before the ink covers the elevated pads.

There may be provided a printer for applying ink to a substrate to form a pattern, the printer may include a printing unit that may include print heads for ink jetting solder ink; a freezing unit; and a controller for controlling the printing unit and the freezing unit by controlling multiple printing iterations; wherein during a single printing iteration (a) the prints heads may be configured to perform a flooding, using jets of ink, the substrate with ink, such that the ink advances within edges of the pattern; and (b) the freezing units may be configured to perform a freezing of the ink before the ink exceeds the edges of the pattern; wherein at least one of the following may be true: (i) the freezing units may be configured to perform the freezing of the ink using radiation; and (ii) the printer may include a vibration module that may be configured to perform a vibrating of the substrate during a vibration period that at least partially overlaps at least one of the flooding and the freezing.

The vibration module may be configured to vibrate the substrate during the entire printing period.

The printing period may end when the freezing starts or before the freezing starts.

The vibration module may be configured to end the vibration of the substrate after the freezing starts.

The vibration module may be configured to introduce vibrations to the substrate that may be identical to each other.

The vibration module may be configured to introduce vibrations that differ from each other.

The vibration module may be configured to reduce an intensity of vibrations towards an end of the printing period.

The controller may be configured to determine at least one parameter out of a vibrating parameter, a flooding parameter and a freezing parameter in response to an occurrence of a failure of the printing unit.

The at least one parameter may include a delay between a beginning of the flooding and a beginning of the freezing.

The controller may be configured to expand the delay when the failure of the printing unit may be a non-printing nozzle of a printing unit.

The failure may be detected by the printer or any another device. For example—The printer may include an image processor that may be configured to detect the occurrence of the failure of the printing unit by image processing an image of previous pattern that was previously printed by the printing unit.

The printing unit may be configured to flood one or more regions of the substrate; and print ink on one or more other regions of the substrate without flooding the one or more other regions.

The printing unit may be configured to flood a region of the substrate; wherein the flooding of the region may be preceded by printing without flooding a border of the region.

The pattern may be delimited by elevated pads; and wherein the freezing may be executed before the ink covers the elevated pads.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1-2 are a top view and a cross sectional view of an inkjet printer;

FIG. 3 illustrates solder mask ink and a substrate PCB according to an embodiment of the invention;

FIG. 4 is a flow chart according to an embodiment of the invention;

FIG. 5 is a flow chart according to an embodiment of the invention; and

FIG. 6 illustrates various timing diagrams according to an embodiment of the invention.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

The figure may or may not be of scale.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a printer capable of executing the method and should be applied mutatis mutandis to a non-transitory computer readable medium that stores instructions that once executed by a computer result in the execution of the method.

Any reference in the specification to a printer should be applied mutatis mutandis to a method that may be executed by the printer and should be applied mutatis mutandis to a non-transitory computer readable medium that stores instructions that may be executed by the printer.

Any reference in the specification to a non-transitory computer readable medium should be applied mutatis mutandis to a printer capable of executing the instructions stored in the non-transitory computer readable medium and should be applied mutatis mutandis to method that may be executed by a computer that reads the instructions stored in the non-transitory computer readable medium.

According to an embodiment of the invention there is provided a printer and a method for printing ink on a substrate such as but not limited to a printed circuit board (PCB).

According to an embodiment of the invention an ink such as solder mask ink is printed on a substrate such as a PCB that includes elevated features and lower features. Wherein during the single phase the substrate is flooded with solder mask ink and the solder mask ink may contact the sidewalls of the elevated features and frozen (during the same phase) before covering the top of the elevated features.

The freezing may include curing the solder mask ink using heat and/or UV radiation and/or using a thermal freezing unit.

During the flooding (or at least during a part of the flooding) the substrate may be vibrated. The vibration improves the spreading of the solder mask ink. The vibrations may include one or more vibration pulses. The amplitude of the vibrations may remain constant during the entire printing phase or may change (for example may have lower amplitude during the end of the printing phase). One or more vibrating pulse may be applied after the ink is jetted and before the freezing.

The printing process may include multiple phases, at least some of which include vibrating and printing.

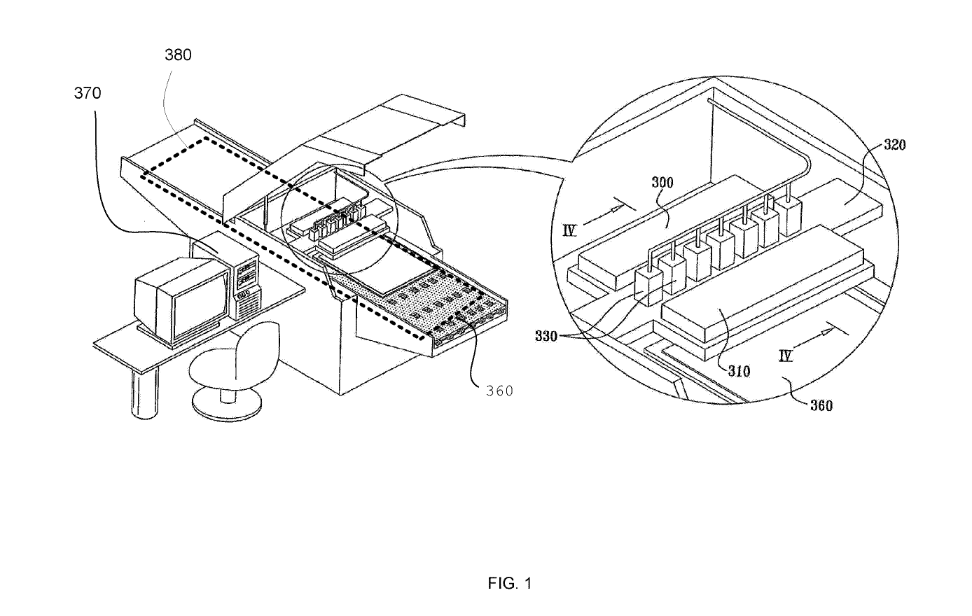

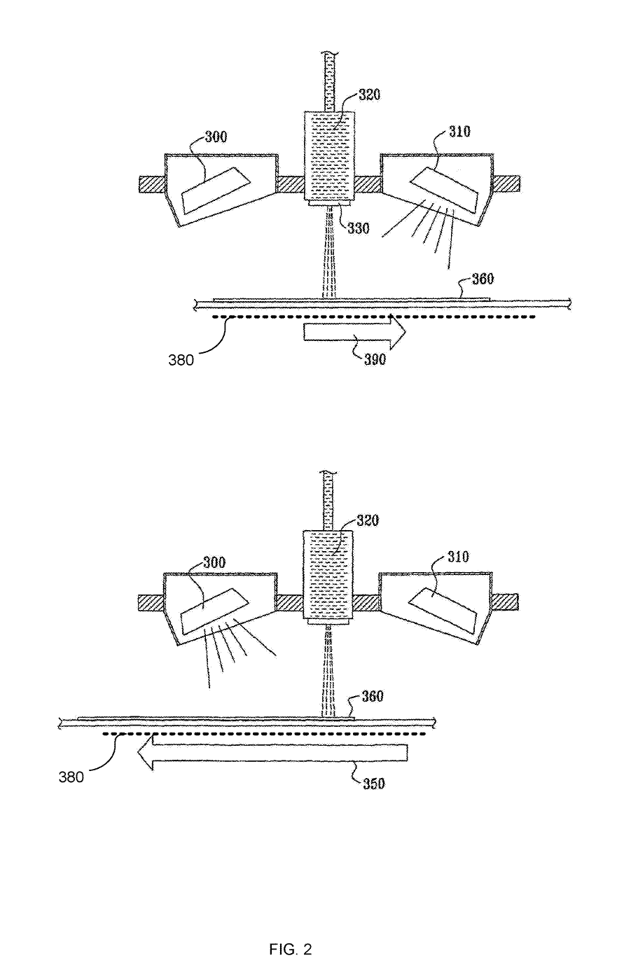

FIGS. 1-2 illustrate an example of a printer 300. The printer has print heads 330 for ink jetting solder mask ink 320, freezing units 300 and 310 placed on both sides of the print heads 330, controller 370 for controlling the printing and freezing process, conveyor 360 for conveying the PCB and a vibration module 380 for vibrating the PCB. It is noted that the vibration module 380 may be positioned between the PCB and the conveyor 360. Arrows 390 and 350 of FIG. 2 illustrate a direction of movement of the PCB.

The vibration module 380 may include one or more motors for introducing vibrations and one or more vibrating elements that can be vibrated under the control of the one or more motors. The one or more vibrating elements may contact the printed circuit board, the conveyor and the like. The vibration module 380 is illustrated as being larger than the PCB—but it can be smaller than the PCB. The vibration module 380 may include multiple spaced apart modules that may contact the PCB in one or more locations while the PCB is moved by the conveyor.

The vibrations may introduce periodical or non-periodical vibrational waves through the PCB.

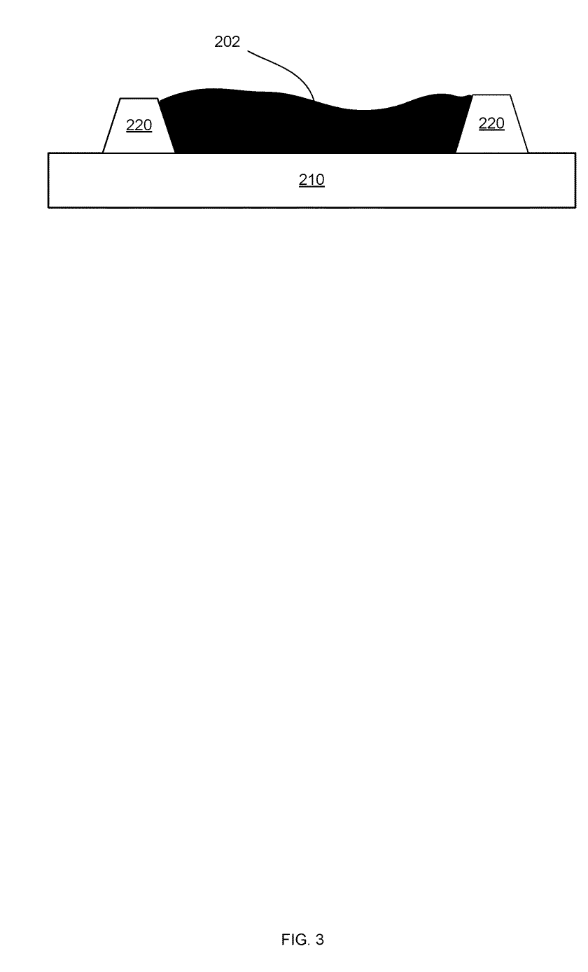

FIG. 3 illustrates solder mask ink 202 that is printed on substrate 210—and is delimited between elevated features 220 of the substrate.

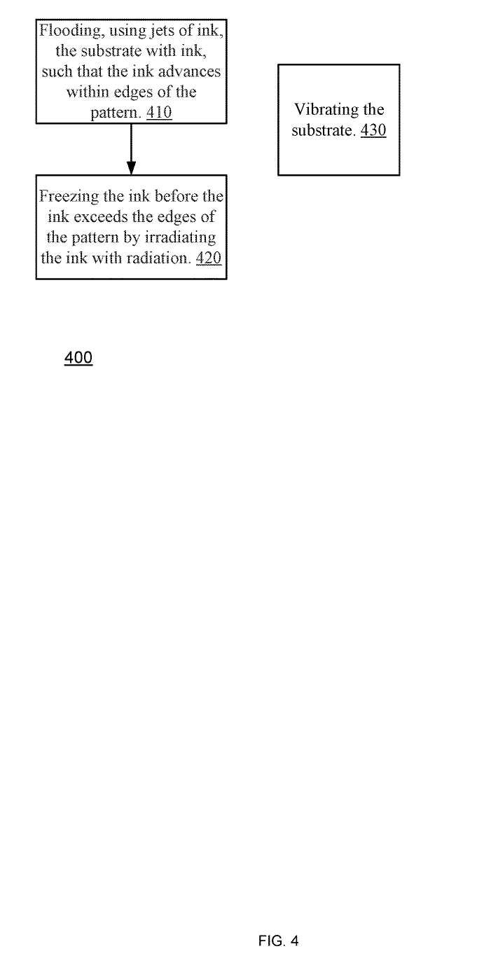

FIG. 4 illustrates a method 400 according to an embodiment of the invention.

Method 400 is for applying ink to a substrate to form a pattern. Method 400 may include performing a single printing iteration. The single printing iteration is aimed to cover one or more areas of the substrate with the pattern.

Method 400 may start by step 410 of flooding the substrate with ink using jets of ink, such that the ink advances within edges of the pattern. The jets of ink partially or fully cover the substrate.

At least some of the edges of the pattern may be formed by the topology (structure) of the substrate or otherwise formed before the printing iteration. For example—these edges may be elevated in relation to the interior of the pattern or may be printed (by a flooding or non-flooding printing process) before executing step 410. The edges of the patterns may be pad edges, any structural elements of the object or any structural elements that are attached to the object. It is noted that one or more edges of the pattern may be defined by the printing process (steps 410 and 420) itself—by allowing the ink to propagate during the flooding and then stopping the propagation by freezing the ink.

Step 410 may be followed by step 420 of freezing the ink before the ink exceeds the edges of the pattern by irradiating the ink with radiation.

The delay between the beginning of the flooding and the beginning of the freezing may be set in advance (for example 100 milliseconds, one or more seconds, one or more minutes and the like). The delay may be responsive to the viscosity of the ink, to the printing rate (ink printed per time unit), to the volume of space that should be filled by the ink, and the like. One such embodiment utilized a 1 minute delay between jetting the ink and freezing it with actinic radiation.

Method 400 may also include step 430 of vibrating the substrate. The vibrating may at least partially overlap step 410 and/or may at least partially overlap step 420.

The vibrating may speed up the propagation of the ink and/or make the distribution of the ink more homogeneous.

The vibrating may include inducing one or more vibrations that may include one or more vibration pulses. The amplitude of the vibrations may remain constant during the entire printing phase or may change (for example may have lower amplitude during the end of the printing phase). One or more vibrating pulse may be applied after the ink is ink jetted and before the freezing.

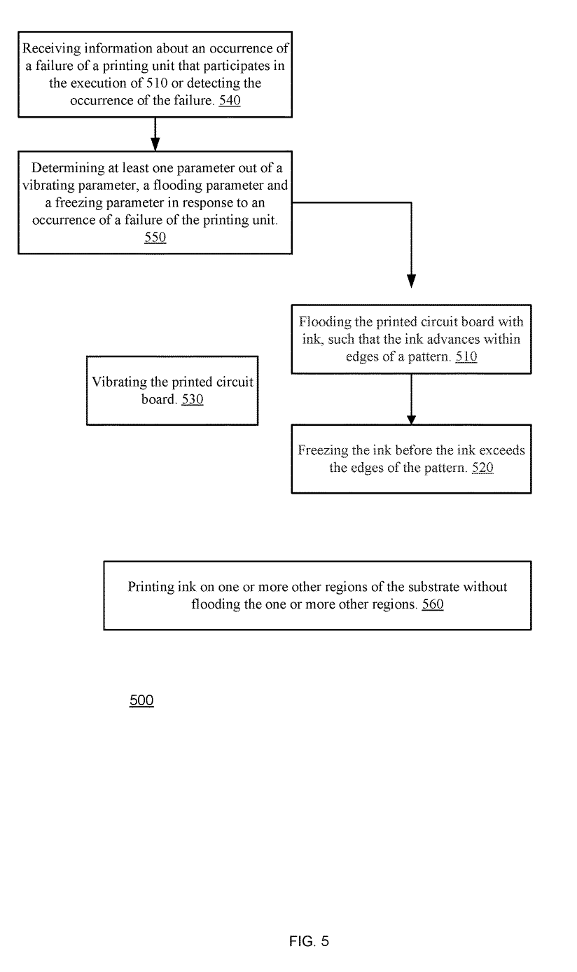

FIG. 5 illustrates a method 500 according to an embodiment of the invention.

Method 500 is for applying ink to a printed circuit board.

Method 500 may start by step 510 of flooding the printed circuit board with ink, such that the ink advances within edges of a pattern.

Step 510 may be followed by step 520 of freezing the ink before the ink exceeds the edges of the pattern.

The pattern may be defined by elevated pads and the freezing may occur before the ink covers the elevated pads.

Method 500 may also include step 530 of vibrating the printed circuit board.

The vibrating may at least partially overlap step 510, may at least partially overlap step 520, and the like.

The vibrating may include inducing one or more vibrations that may include one or more vibration pulses. The amplitude of the vibrations may remain constant during the entire printing phase or may change (for example may have lower amplitude during the end of the printing phase). One or more vibrating pulse may be applied after the ink is jetted and before the freezing.

Step 530 may be executed during only a part of step 510, during the entirety of step 510, during a part of step 520, during only a part of step 520, and during a combination of at least a part of step 510 and at least a part of step 520.

The vibrating may include vibrating the entire PCB, vibrating only one or more parts of the PCB, printing a portion of the PCB that “covers” the pattern, introducing vibrations by vibrating elements that contacts the PCB and/or by a vibrating element that does not contact the PCB but contacts other elements that contact the PCB, and the like. The vibrating element may be of any shape or size.

Method 500 may also include step 540 of receiving information about an occurrence of a failure of a printing unit that participates in the execution of step 510 or detecting the occurrence of the failure.

Step 540 may be followed by step 550 of determining at least one parameter out of a vibrating parameter, a flooding parameter and a freezing parameter in response to an occurrence of a failure of the printing unit.

The determining may be followed by step 510, 520 and 530.

The printing unit may include multiple print heads and the failure may be a non-printing nozzle. The failure may represent an actual or expected gap in the pattern (for example a missing nozzle trace). In order to compensate for the lack of ink the freezing process may be delayed, the flooding process may be lengthened, the flooding may involve increasing the printing rate (amount of ink per time unit), the freezing intensity may be lowered, and the like.

Step 540 may include detecting the occurrence of the failure of the printing unit by image processing an image of a pattern that was previously printed by the printing unit.

Step 510 may be applied on one or more regions of the substrate. Method 500 may also include step 560 of printing ink on one or more other regions of the substrate without flooding the one or more other regions.

Step 510 may involve flooding a region of the substrate. Step 510 may be preceded by printing without flooding a border of the region.

Method 500 may be applied on an object that is not a PCB.

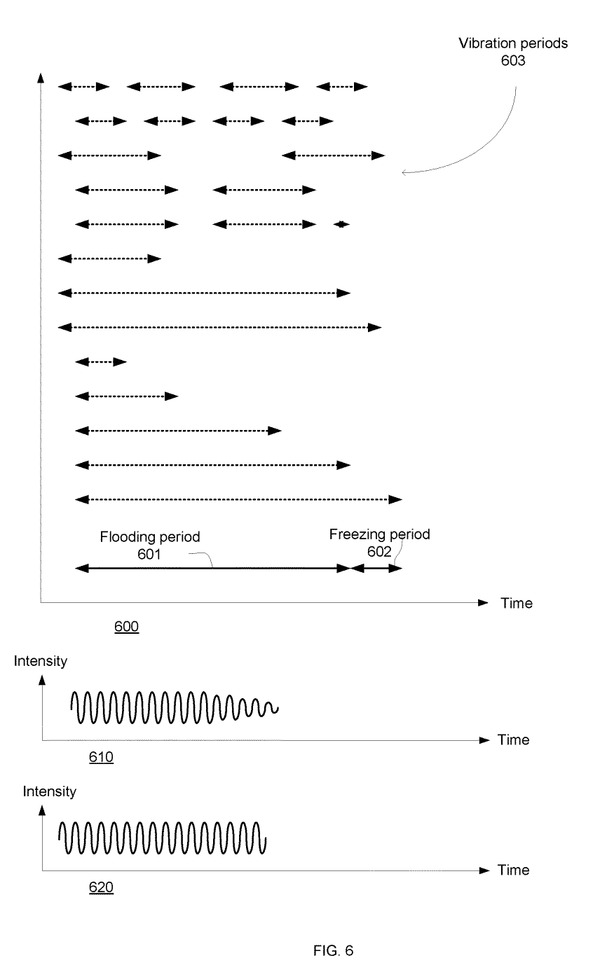

FIG. 6 illustrates timing diagrams 600, 610 and 620.

Timing diagram 600 illustrates an example of a flooding period 601 that is followed by a freezing period 602. Timing diagram 600 also illustrates different examples of one or more vibration periods. For example—there are single vibration periods of different durations and there are combinations of multiple vibration periods. There may be a number of vibration periods during each printing iteration. During a single printing iteration, the vibration periods may be of the same length, of different length or a combination thereof. Time gaps between vibration periods may be the same, may differ from each other or may be a combination thereof.

The vibration patterns may overlap the flooding period 601, may overlap the freezing period 602, may overlap both flooding and freezing periods, may only partially overlap (by any value between 1 and 99 percent) the flooding period 601, may only partially overlap the freezing period 602, may only partially overlap both flooding and freezing periods, may start before the flooding period, may start at any time within the flooding and freezing period and may end at any time.

Timing diagram 610 illustrates vibrations of varying maxima intensities while timing diagram 620 illustrates vibrations of fixed maxima intensities. The shape and duration of the vibrations may differ from those illustrated in either one timing diagrams 610 and 620.

According to an embodiment of the invention the printing method enables to compensate for malfunctioning print heads. Especially—when some of the nozzles of the print heads are malfunctioning and do not print properly (or not print at all) the flooding of the substrate enables the ink to compensate for malfunctions. This flooding may save the need to inspect the substrate after the flooding in order to detect gaps in the coverage of the ink (due to malfunctions) and a further printing process that may follow the finding of the defect.

The flooding may last few seconds, few tenths of second, below a minute, a minute and even more than a minute.

The flooding and freezing (as well as other steps of methods 300 and 400) can be applied for printing on PCBs or other objects, for zero clearance application or for other applications—depending on the ink properties, viscosity and surface tension.

The duration of the flooding can be changed to get the desired coverage, and the like. The duration of the flooding may depend upon the viscosity of the jetted ink.

The methods can be applied for elimination of missing nozzle traces.

The methods can be applied for overcoming ink on ink vs. ink on substrate behavior differences. For example—when printing few layers of ink (one layer above the other) then the result of having missing nozzles (malfunctioning nozzles) can be seen as elongated gaps such as lines—and especially scratches. This can be solved by using flooding techniques when printing one or more layers—especially (but not limited to) the last layer (ink on ink) without using UV lamp immediately after printing. This allows the ink to flood and blur the gap caused by the missing nozzles. After a while the ink may be cured.

Especially—allowing the ink to flow prior to the UV freeze facilitates ink flow that can be localized by the printing algorithm. Some areas will be printed and flooded, while others will not.

The methods may include contour printing followed by filling the contour and flooding to allow fast low resolution printing of large solid coverage areas.

The method can be used for introducing desired physical properties to the cured ink, such as flexibility.

The methods can be used for improving adhesion to the substrate by allowing the ink to flood the substrate thus improving substrate wetting

Any reference to the term “comprising” or “having” should be interpreted also as referring to “consisting of” or “essentially consisting of”. For example—a method that comprises certain steps can include additional steps, can be limited to the certain steps or may include additional steps that do not materially affect the basic and novel characteristics of the method—respectively.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

The terms “comprising”, “having”, “consisting” and “consisting essentially of” are used in an interchangeable manner.

We claim:

1. A method for applying ink to a substrate to form a pattern, the method comprising:
performing a single printing iteration that comprises:
flooding, using jets of ink, the substrate with ink, such that the ink advances within edges of the pattern; and
freezing the ink before the ink exceeds the edges of the pattern by irradiating the ink with radiation.

2. The method according to claim 1 further comprising vibrating the substrate during a vibration period that at least partially overlaps at least one of the flooding and the freezing.

3. A method for applying ink to a printed circuit board to form a pattern, the method comprising:
flooding the printed circuit board with ink, such that the ink advances within edges of the pattern;
freezing the ink before the ink exceeds the edges of the pattern; and
vibrating the printed circuit board during a vibration period that at least partially overlaps at least one of the flooding and the freezing.

4. The method according to claim 3, comprising vibrating the printed circuit board during the entire printing period.

5. The method according to claim 3, wherein the printing period ends when the freezing starts or before the freezing starts.

6. The method according to claim 3, wherein the vibrating ends after the freezing starts.

7. The method according to claim 3, wherein the vibrating comprises introducing vibrations that are identical to each other.

8. The method according to claim 3, wherein the vibrating comprises introducing vibrations that differ from each other.

9. The method according to claim 3, wherein the vibrating comprises reducing an intensity of vibrations towards an end of the printing period.

10. The method according to claim 3, wherein the flooding is executed by a printing unit; and
wherein the method comprises determining at least one parameter out of a vibrating parameter, a flooding parameter and a freezing parameter in response to an occurrence of a failure of the printing unit.

11. The method according to claim 10, wherein the at least one parameter comprises a delay between a beginning of the flooding and a beginning of the freezing.

12. The method according to claim 11 comprising expanding the delay when the failure of the printing unit is a non-printing nozzle of a printing unit.

13. The method according to claim 10, comprising detecting the occurrence of the failure of the printing unit by image processing an image of previous pattern that was previously printed by the printing unit.

14. The method according to claim 3 wherein the flooding comprises flooding one or more regions of the substrate; and printing ink on one or more other regions of the substrate without flooding the one or more other regions.

15. The method according to claim 3 wherein the flooding comprises flooding a region of the substrate; wherein the flooding of the region is preceded by printing without flooding a border of the region.

16. The method according to claim 3 wherein the pattern is delimited by elevated pads; and
wherein the freezing is executed before the ink covers the elevated pads.

17. A printer for applying ink to a printed circuit board to form a pattern, the printer comprises:
a printing unit that comprises print heads for ink jetting solder ink;
a freezing unit;
a vibration module; and
a controller for controlling the printing unit and the freezing unit by controlling multiple printing iterations;
wherein during a single printing iteration (a) the print heads are configured to perform a flooding, using jets of ink, the printed circuit board with ink, such that the ink advances within edges of the pattern; and (b) the freezing units are configured to perform a freezing of the ink before the ink exceeds the edges of the pattern;
wherein the vibration module is configured to perform a vibrating of the printed circuit board during a vibration period that at least partially overlaps at least one of the flooding and the freezing.

18. A non-transitory computer readable medium that stores instructions that once executed by a printer cause the printer to execute the steps of performing a single printing iteration that comprises: flooding, using jets of ink, a substrate with ink, such that the ink advances within edges of the pattern; and freezing the ink before the ink exceeds the edges of the pattern by irradiating the ink with radiation.

19. A non-transitory computer readable medium that stores instructions that once executed by a printer cause the printer to execute the steps of performing a single printing iteration that comprises: flooding a printed circuit board with ink, such that the ink advances within edges of the pattern; freezing the ink before the ink exceeds the edges of the pattern; and vibrating the printed circuit board during a vibration period that at least partially overlaps at least one of the flooding and the freezing.
